(19) United States
(12) Patent Application Publication
(10) Pub. No.: US 2026/0005652 A1
(43) Pub. Date: Jan. 1, 2026

(54) TRACKER CIRCUIT, TRACKER MODULE, AND VOLTAGE SUPPLY METHOD

(71) Applicant: Murata Manufacturing Co., Ltd., Nagaokakyo-shi (JP)

(72) Inventors: Atsuya HIRONO, Nagaokakyo-shi (JP); Takeshi Kogure, Nagaokakyo-shi (JP); Taichi yamaguchi, Nagaokakyo-shi (JP); Naohide Tomita, Nagaokakyo-shi (JP)

(21) Appl. No.: 19/322,778

(22) Filed: Sep. 9, 2025

Related U.S. Application Data
(63) Continuation of application No. PCT/JP2024/006698, filed on Feb. 26, 2024.

(30) Foreign Application Priority Data
Mar. 27, 2023 (JP) 2023-049826

(51) Int. Cl. H03F 1/02; H03F 3/24

(52) U.S. Cl. CPC H03F 1/0227; H03F 3/245; H03F 2200/102; H03F 2200/105; H03F 2200/435; H03F 2200/451

(57) ABSTRACT

A tracker circuit is provided that includes a converter circuit configured to convert a battery voltage into a first regulated voltage, and a supply modulator that receives the battery voltage and the first regulated voltage. The supply modulator outputs a modulated voltage to a power amplifier by selectively outputting at least one of a plurality of discrete voltages that includes the battery voltage and the first regulated voltage.

### CROSS REFERENCE TO RELATED APPLICATIONS

This application is a continuation of International Application No. PCT/JP2024/006698, filed Feb. 26, 2024, which claims priority to Japanese Patent Application No. Application No. 2023-049826, filed Mar. 27, 2023, the contents of each of which are hereby incorporated by reference in their entireties.

### TECHNICAL FIELD

The present disclosure relates to a tracker circuit, a tracker module, and a voltage supply method.

### BACKGROUND

U.S. Pat. No. 8,829,993 describes a technique in which power efficiency is improved by applying a digital envelope tracking (ET) mode to a power amplifier, the digital ET mode being a mode in which a plurality of discrete voltages are supplied.

However, in a digital ET mode, low power consumption and miniaturization are required.

### SUMMARY OF THE INVENTION

Therefore, the exemplary aspects of the present disclosure provide a tracker circuit, a tracker module, and a voltage supply method that are configured to provide low power consumption while also offering miniaturization.

In an exemplary aspect, a tracker circuit is provided that includes a first converter circuit configured to convert an input voltage into a first regulated voltage, and a supply modulator configured to receive the input voltage and the first regulated voltage. The supply modulator is further configured to output a modulated voltage to a power amplifier by selectively outputting at least one discrete voltage of a plurality of discrete voltages including the input voltage and the first regulated voltage.

In another exemplary aspect, a tracker module is provided that includes a module laminate, and an integrated circuit disposed on the module laminate. The integrated circuit includes a switch included in a first converter circuit configured to convert an input voltage into a first regulated voltage, and a switch included in a supply modulator that is configured to receive the input voltage and the first regulated voltage. The supply modulator is further configured to selectively output, based on an envelope signal, at least one discrete voltage of a plurality of discrete voltages that includes the input voltage and the first regulated voltage to a power amplifier.

In another exemplary aspect, a voltage supply method is provided that includes converting an input voltage into a first regulated voltage, and selectively outputting, based on an envelope signal, at least one discrete voltage of a plurality of discrete voltages that includes the input voltage and the first regulated voltage to a power amplifier.

With the tracker circuit, the tracker module and the voltage supply method of the present disclosure, low power consumption and miniaturization is realized.

### BRIEF DESCRIPTION OF DRAWINGS

FIG. 1A is a graph showing an example of the transition of a power supply voltage in an APT mode.

FIG. 1B is a graph showing an example of the transition of a power supply voltage in an analog ET mode.

FIG. 1C is a graph showing an example of the transition of a power supply voltage in a digital ET mode.

FIG. 2 is a circuit configuration diagram of a communication device according to an exemplary embodiment.

FIG. 3 is a circuit configuration diagram of a power amplifier according to the exemplary embodiment.

FIG. 4A is a circuit configuration diagram of a tracker circuit according to the exemplary embodiment.

FIG. 4B is a diagram showing an output waveform of a power supply voltage of the tracker circuit according to the exemplary embodiment.

FIG. 5 is a flowchart showing a voltage supply method according to an exemplary embodiment.

FIG. 6A is a circuit configuration diagram of a tracker circuit according to Modification 1 of the exemplary embodiment.

FIG. 6B is a diagram showing an output waveform of a power supply voltage of the tracker circuit according to Modification 1 of the exemplary embodiment.

FIG. 7A is a circuit configuration diagram of a tracker circuit according to Modification 2 of the exemplary embodiment.

FIG. 7B is a diagram showing an output waveform of a power supply voltage of the tracker circuit according to Modification 2 of the exemplary embodiment.

FIG. 8A is a circuit configuration diagram of a tracker circuit according to Modification 3 of the exemplary embodiment.

FIG. 8B is a diagram showing an output waveform of a power supply voltage of the tracker circuit according to Modification 3 of the exemplary embodiment.

FIG. 9A is a circuit configuration diagram of a tracker circuit according to Modification 4 of the exemplary embodiment.

FIG. 9B is a diagram showing an output waveform of a power supply voltage of the tracker circuit according to Modification 4 of the exemplary embodiment.

FIG. 10 is a flowchart showing a voltage supply method according to Modification 4 of the exemplary embodiment.

FIG. 11 is a plan view of a tracker module according to the exemplary embodiment.

### DETAILED DESCRIPTION OF EMBODIMENTS

Exemplary embodiments of the present disclosure will be described in detail below with reference to the drawings. All the embodiments described below are comprehensive or specific examples. The numerical values, shapes, materials, components, arrangement of components, connection forms and the like shown in the following embodiments are examples and are not intended to limit the present disclosure.

It is generally be noted that each drawing is schematic with emphasis, omissions, or proportions adjusted as appropriate to illustrate the exemplary aspects of the present disclosure, and is not necessarily strictly illustrative, and may differ from actual shapes, positional relationships, and proportions. In each drawing, substantially identical components are denoted by the same reference signs, and duplicate descriptions may be omitted or simplified.

In the following drawings, the x-axis and the y-axis are axes orthogonal to each other on a plane parallel to a main surface of a substrate. Specifically, in exemplary aspects where the substrate has a rectangular shape in plan view, the x-axis is parallel to a first side of the substrate, and the y-axis is parallel to a second side orthogonal to the first side of the substrate. Further, the z-axis is an axis perpendicular to the main surface of the substrate, and the positive direction of the z-axis indicates an upward direction and the negative direction of the z-axis indicates a downward direction.

In the component arrangement of the exemplary aspects of the present disclosure, the expression “in the plan view of the substrate” can refer to viewing an object or component orthographically projected onto the xy plane from the positive side of the z-axis. Moreover, the expression “A overlaps with B in plan view” can indicate that at least a portion of a region obtained by orthographically projecting A onto the xy plane overlaps with at least a portion of a region obtained by orthographically projecting B onto the xy plane. Further, the expression “A is disposed between B and C” can indicate that at least one of a plurality of line segments connecting any point in B and any point in C passes through A.

In the component arrangement of the exemplary aspects of the present disclosure, the expression “a component is disposed on the substrate” includes that the component is disposed on a main surface of the substrate and that the component is disposed in the substrate. The expression “a component is disposed on the main surface of the substrate” includes that the component is disposed above the main surface without being in contact with the main surface (for example, a component is stacked on another component disposed in contact with a main surface) in addition to that the component is disposed in contact with the main surface of the substrate. The expression “a component is disposed on the main surface of the substrate” may also include that the component is disposed in a recessed portion formed in the main surface. The expression “a component is disposed in the substrate” includes that the entire component is disposed between both main surfaces of the substrate but a portion of the component is not covered by the substrate and that only a portion of the component is disposed in the substrate, in addition to that the component is encapsulated in a substrate.

In circuit configurations of the present disclosure, the term “connected” includes not only being directly connected by connection terminals and/or wiring conductors, but also can include being electrically connected via other circuit elements. The expression “connected between A and B” can include “connected to both A and B, between A and B”.

Further, in the present disclosure, the expression “a component (element) A is arranged in series in a path B” can indicate that both the signal input end and the signal output end of the component (element) A are connected to the wiring, the electrodes, or the terminals forming the path B.

Further, in the component arrangement of the exemplary aspects of the present disclosure, the expression “A is disposed adjacent to B” can indicate that A and B are disposed close to each other; and specifically, no other circuit components exist in a space where A faces B. In other words, the expression “A is disposed adjacent to B” can indicate any of a plurality of line segments from any point on the surface of A facing B to B in the direction normal to the surface does not pass through circuit components other than A and B. Here, the circuit components refer to components that include active elements and/or passive elements. That is, the circuit components include active components such as transistors or diodes, and passive components such as inductors, transformers, capacitors, or resistors, but do not include electromechanical components such as terminals, connectors, or wiring.

In the exemplary aspects of the present disclosure, the term “terminal” can indicate a point at which the conductor in an element terminates. It is also noted that when the impedance of the conductor between elements is sufficiently low, the terminal is also interpreted as any point on the conductor between elements or as the entire conductor, instead of being interpreted only as a single point.

Further, for purposes of this disclosure, the terms indicating relationships between elements, such as “parallel” and “orthogonal”, and the terms indicating the shape of elements, such as “rectangular”, as well as numerical ranges do not represent only strict meanings, but also include substantially equivalent ranges, for example, with errors of about several percent.

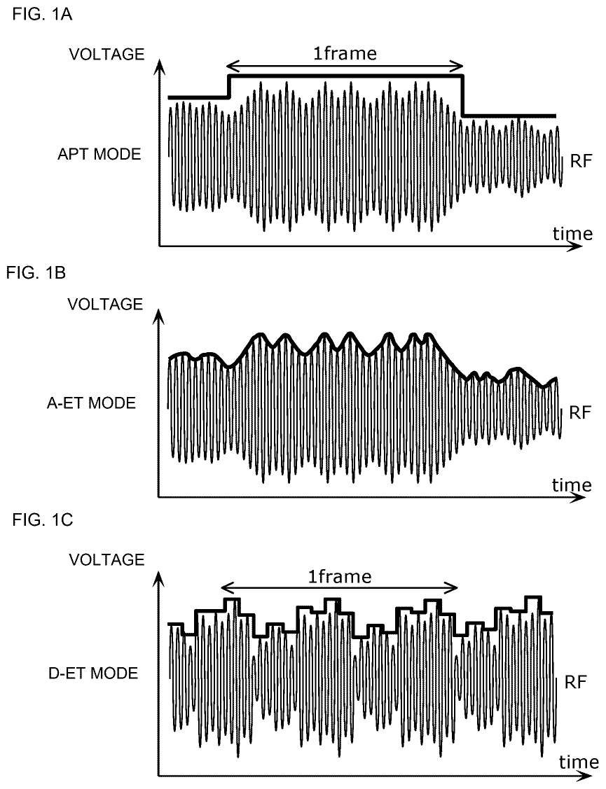

First, a tracking mode, as a technique for amplifying radio frequency signals with high efficiency, will be described, in which a power supply voltage dynamically regulated with the lapse of time based on the radio frequency signals is supplied to a power amplifier. A tracking mode is a mode that dynamically regulates a power supply voltage to be applied to a power amplifier. There are several types of tracking modes. Here, an average power tracking (APT) mode and an envelope tracking (ET) mode (including an analog ET mode and a digital ET mode) will be described with reference to FIGS. 1A to 1C. In each of FIGS. 1A to 1C, the horizontal axis represents time and the vertical axis represents voltage. Further, the thick solid line represents a power supply voltage and the thin solid line (e.g., a waveform) represents a modulated signal.

FIG. 1A is a graph showing an example of the transition of a power supply voltage in an APT mode. In the APT mode, the power supply voltage is changed to a plurality of discrete voltage levels in units of one frame based on the average power. As a result, the power supply voltage signal forms a rectangular wave.

For purposes of this disclosure, a frame can be a unit that forms a radio frequency signal (e.g., modulated signal). For example, in 5th Generation New Radio (5GNR) and Long Term Evolution (LTE), a frame includes 10 sub-frames, each sub-frame includes a plurality of slots, and each slot is composed of a plurality of symbols. The sub-frame length is 1 ms, and the frame length is 10 ms.

Moreover, according to an exemplary aspect, a mode in which the voltage level varies in units of one frame or larger units based on the average power is called an APT mode. The APT mode is distinguished from a mode in which the voltage level varies in units of smaller than 1 frame (for example, sub-frame, slot, or symbol).

FIG. 1B is a graph showing an example of the transition of a power supply voltage in an analog ET mode. In the analog ET mode, the envelope of a modulated signal is tracked by continuously varying, based on an envelope signal, the power supply voltage.

The envelope signal is a signal that indicates the envelope of the modulated signal. The envelope value is expressed, for example, by the square root of (I²+Q²). Here, (I, Q) represents a constellation point. The constellation point is a point that represents a signal modulated by digital modulation on a constellation diagram. (I, Q) is determined by, for example, a Baseband Integrated Circuit (BBIC) based on, for example, transmission information.

FIG. 1C is a graph showing an example of the transition of a power supply voltage in a digital ET mode. In the digital ET mode, the envelope of a modulated signal is tracked by varying, based on an envelope signal, the power supply voltage to a plurality of discrete voltage levels in one frame. As a result, the power supply voltage signal forms a rectangular wave.

### EXEMPLARY EMBODIMENTS

An embodiment will be described below.

### 1 Circuit Configuration of Communication Device 5

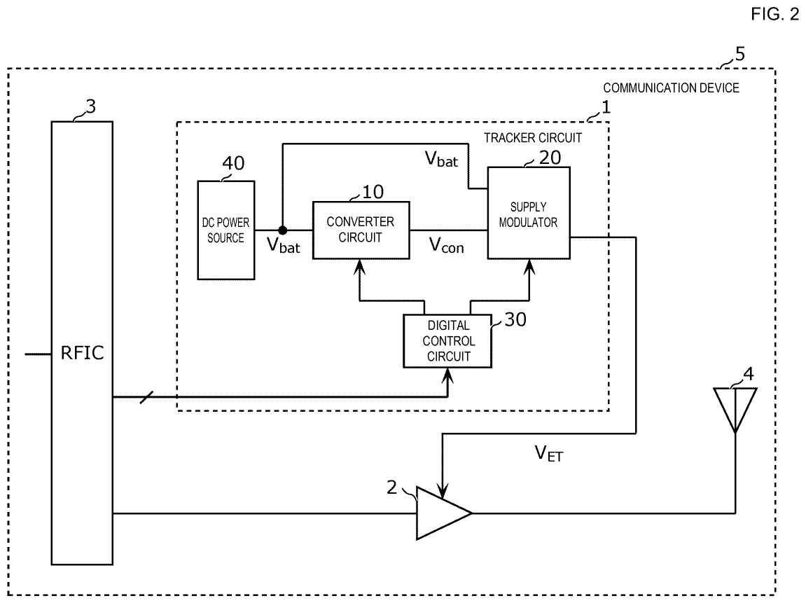

First, a communication device 5 according to the present embodiment will be described with reference to FIG. 2. FIG. 2 is a circuit configuration diagram of the communication device 5 according to the present embodiment.

FIG. 2 is an exemplary circuit configuration, and the communication device 5 may be implemented using any of a wide variety of circuit implementations and circuit techniques. Therefore, the description of the communication device 5 provided below is not to be interpreted in a limited manner.

According to an exemplary aspect, the communication device 5 corresponds to user equipment (UE) in a cellular network; typical examples of the communication device 5 include a mobile phone, a smartphone, a tablet computer, and a wearable device. It is noted that the communication device 5 may also be an Internet of Things (IoT) sensor device, a medical/healthcare device, a car, an unmanned aerial vehicle (UAV) (so-called drone), or an automated guided vehicle (AGV) in exemplary aspects. Further, the communication device 5 may also be configured to function as a base station (BS) in a cellular network.

As shown in FIG. 2, the communication device 5 includes a tracker circuit 1, a power amplifier 2, a radio frequency integrated circuit (RFIC) 3, and an antenna 4.

The tracker circuit 1 can be configured to supply a plurality of discrete voltages to the power amplifier 2 in a digital ET mode. As shown in FIG. 2, the tracker circuit 1 includes a converter circuit 10, a supply modulator 20, a digital control circuit 30, and a DC power source 40.

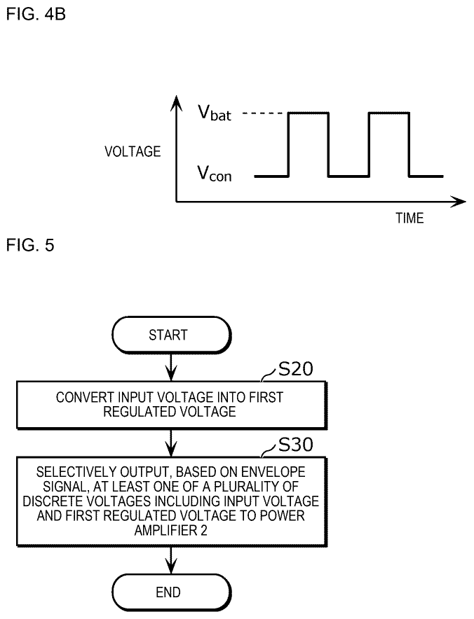

According to an exemplary aspect, the converter circuit 10 is an example of a first converter circuit and is a DCDC converter with one input and one output. The converter circuit 10 can convert a battery voltage Vbat (input voltage) supplied from the DC power source 40 into one variable voltage Vcon (first regulated voltage). The converter circuit 10 can change, based on, for example, a control signal from the RFIC 3, the variable voltage Vcon. The converter circuit 10 according to the present embodiment is a buck converter (step-down) circuit, and can convert the battery voltage Vbat into a variable voltage Vcon lower than the battery voltage Vbat. The circuit configuration of the converter circuit 10 will be described later with reference to FIG. 4A.

The supply modulator 20 can be configured to selectively supply at least one of a plurality of discrete voltages including the battery voltage Vbat and the variable voltage Vcon generated by the converter circuit 10 to the power amplifier 2. In other words, by selecting at least one voltage from the plurality of discrete voltages, the supply modulator 20 can output a modulated voltage, which is at least one voltage of the plurality of discrete voltages, to the power amplifier 2. The circuit configuration of the supply modulator 20 will be described later with reference to FIG. 4A.

The digital control circuit 30 can control the converter circuit 10 and the supply modulator 20 based on a digital control signal from the RFIC 3. Specifically, the digital control circuit 30 can generate and output a control signal for controlling a switch included in the converter circuit 10 and a control signal for controlling a switch included in the supply modulator 20. The circuit configuration of the digital control circuit 30 will be described later with reference to FIG. 4A.

The DC power source 40 can supply the battery voltage Vbat to the converter circuit 10 and the supply modulator 20. A rechargeable battery, for example, can be used as the DC power source 40, but the DC power source 40 is not limited to a rechargeable battery. It is noted that the digital control circuit 30 and the DC power source 40 may be omitted from the tracker circuit 1 in an exemplary aspect.

The antenna 4 transmits the radio frequency signal input from the power amplifier 2. It is noted that the antenna 4 may be omitted from the communication device 5 in an exemplary aspect.

The power amplifier 2 is connected between the RFIC 3 and the antenna 4. Further, the power amplifier 2 is connected to the tracker circuit 1. The power amplifier 2 can amplify a radio frequency signal of a predetermined band received from the RFIC 3 by using a plurality of discrete voltages received from the tracker circuit 1.

The predetermined band is a frequency band for a communication system constructed using a radio access technology (RAT), and is predefined by a standardizing body or the like, such as the 3rd Generation Partnership Project (3GPP®) and the Institute of Electrical and Electronics Engineers (IEEE). Examples of the communication system include a 5GNR system, an LTE system, and a Wireless Local Area Network (WLAN) system.

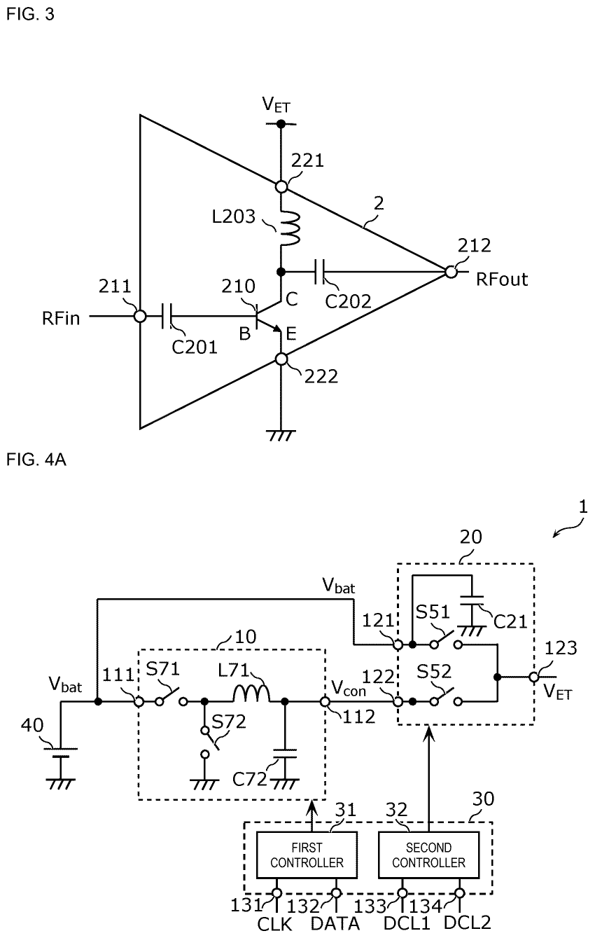

FIG. 3 is a circuit configuration diagram of the power amplifier 2 according to the embodiment. As shown in FIG. 3, the power amplifier 2 includes an amplification transistor 210, capacitors C201 and C202, an inductor L203, a collector terminal 221, an emitter terminal 222, an input terminal 211, and an output terminal 212.

The amplification transistor 210 is, for example, an emitter grounded bipolar transistor having a collector, an emitter, and a base, and is an amplifying element that amplifies a radio frequency current inputted to the base and outputs the amplified radio frequency current from the collector. It is noted that the amplification transistor 210 may alternatively be a field effect transistor having a drain (corresponding to the collector), a source (corresponding to the emitter), and a gate (corresponding to the base) in exemplary aspects.

The collector terminal 221 is directly connected to an output terminal 123 of the supply modulator 20. The emitter terminal 222 is connected to the ground. With such a configuration, since the tracker circuit 1 does not have a filter circuit, the tracker circuit can be miniaturized.

The capacitor C201 is a capacitive element for DC cutting, and is connected between the input terminal 211 and the base of the amplification transistor 210. The capacitor C201 has a function of preventing DC current from leaking to the input terminal 211 due to a DC bias voltage applied from a bias circuit to the base of the amplification transistor 210.

The capacitor C202 is a capacitive element for DC cutting, and is connected between the output terminal 212 and the collector of the amplification transistor 210. The capacitor C202 has a function of removing the DC component of the radio frequency amplified signal superimposed with the DC bias voltage, and the radio frequency amplified signal with the DC component removed is outputted from the output terminal 212.

The inductor L203 is a choke coil, and is connected between the collector terminal 221 and the collector of the amplification transistor 210. The inductor L203 has a function of suppressing leakage of the radio frequency amplified signal amplified by the amplification transistor 210 from the collector terminal 221 to the tracker circuit 1.

It is noted that the power amplifier 2 may have a bias circuit for applying a bias voltage to the base of the amplification transistor 210. Further, the power amplifier 2 may have a bypass capacitor connected between the ground and a path connecting the inductor L203 and the collector terminal 221. Further, the power amplifier 2 may have an inductor connected between the emitter of the amplification transistor 210 and the emitter terminal 222.

With the circuit configuration of the power amplifier 2, in a state in which a power supply voltage V_{ET} is supplied from the tracker circuit 1 to the collector of the amplification transistor 210, a radio frequency signal RFin input from the input terminal 211 becomes a base current Ib flowing from the base to the emitter of the amplification transistor 210. The base current Ib is amplified by the amplification transistor 210 to become a collector current Icc, and a radio frequency signal RFout corresponding to the collector current Icc is outputted from the output terminal 212.

The circuit configuration of the communication device 5 shown in FIG. 2 is an example, and is not limited to such an example. For example, the communication device 5 may include a baseband signal processing circuit that processes signals using an intermediate frequency band lower than the radio frequency signal.

### 2 Circuit Configuration of Tracker Circuit 1

Next, the circuit configuration of the tracker circuit 1 will be described with reference to FIGS. 4A and 4B. FIG. 4A is a circuit configuration diagram of the tracker circuit 1 according to the embodiment. FIG. 4B is a diagram showing the output waveform of the power supply voltage V_{ET} of the tracker circuit 1 according to the embodiment.

FIG. 4A is an exemplary circuit configuration, and the tracker circuit 1 may be implemented using any of a wide variety of circuit implementations and circuit techniques. Therefore, the description of each circuit provided below is not to be interpreted in a limited manner.

As described above, the tracker circuit 1 includes the converter circuit 10, the supply modulator 20, the digital control circuit 30, and the DC power source 40. It is noted that the tracker circuit 1 may include a filter circuit (not shown) between the supply modulator 20 and the power amplifier 2 in an exemplary aspect.

The circuit configurations of the converter circuit 10, the supply modulator 20, and the digital control circuit 30 will be described below in this order.

### [2.1 Circuit Configuration of Converter Circuit 10]

The converter circuit 10 according to the present embodiment is a buck converter (step-down) circuit, and includes an input terminal 111, an output terminal 112, switches S71 and S72, a power inductor L71, and a capacitor C72.

The input terminal 111 is an example of a first input terminal, and is a terminal for receiving the battery voltage Vbat from the DC power source 40. The input terminal 111 is connected, outside the converter circuit 10, to the DC power source 40 and connected, inside the converter circuit 10, to the switch S71.

The output terminal 112 is an example of a first output terminal, and is a terminal for supplying the variable voltage Vcon to the supply modulator 20. The output terminal 112 is connected, outside the converter circuit 10, to an input terminal 122 (first terminal) of the supply modulator 20, and is connected, inside the converter circuit 10, to the power inductor L71.

The power inductor L71 is an example of a first power inductor, and is an inductor used for raising and lowering a DC voltage. The input end of the power inductor L71 is connected to the switches S71 and S72, and the output end of the power inductor L71 is connected to the output terminal 112.

The switch S71 is an example of a first switch, and is connected between the input terminal 111 and the input end of the power inductor L71. Specifically, the switch S71 includes a terminal connected to the input terminal 111 and a terminal connected to the input end of the power inductor L71. In such a connection configuration, the switch S71 can switch the connection and disconnection between the input terminal 111 and the input end of the power inductor L71 by being switched ON and OFF.

The switch S72 is an example of a second switch, and is connected between the input end of the power inductor L71 and the ground. Specifically, the switch S72 includes a terminal connected to the input end of the power inductor L71 and a terminal connected to the ground. In such a connection configuration, the switch S72 can switch the connection and disconnection between the input end of the power inductor L71 and the ground by being switched ON and OFF.

The capacitor C72 is an example of a first capacitor, and is connected between the ground and a path between the power inductor L71 and the output terminal 112. Specifically, one of the two electrodes of the capacitor C72 is connected to the power inductor L71 and the output terminal 112, and the other of the two electrodes of the capacitor C72 is connected to the ground.

The converter circuit 10 configured as described above can convert the battery voltage Vbat (input voltage) into a variable voltage Vcon (first regulated voltage) lower than the battery voltage Vbat.

With the tracker circuit 1 according to the present embodiment, the power supply voltage V_{ET} output from the output terminal 123 has, for example, an output waveform as shown in FIG. 4B. As the digital ET mode of the tracker circuit 1, for example, the battery voltage Vbat is applied to a voltage corresponding to the peak power of the power amplifier 2, and the variable voltage Vcon is applied to a voltage corresponding to a power lower than the peak power. It is noted that the voltage corresponding to the peak power of the power amplifier 2 refers to a power supply voltage optimized for the power-added efficiency of the power amplifier 2 at the peak output power of the radio frequency signal amplified by the power amplifier 2.

Thus, a power supply voltage V_{ET} optimized for the power level lower than the peak power of the power amplifier 2 can be supplied at the variable voltage Vcon (first regulated voltage).

It is noted that the configuration of the converter circuit 10 shown in FIG. 4A is an example, and is not limited to such an example. For example, some of the switches S71 and S72 may be replaced with diode(s) in an alterative aspect. Further, the configuration of the converter circuit 10 is an example, and is not limited to such an example. For example, the converter circuit 10 may be a charge pump circuit that can lower the voltage, that is composed of a capacitor and a switch, and that does not include the power inductor L71.

### [2.2 Circuit Configuration of Supply Modulator 20]

Next, the circuit configuration of the supply modulator 20 will be described with reference to FIG. 4A. The supply modulator 20 includes input terminals 121 and 122, switches S51 and S52, the output terminal 123 and the capacitor C21.

The input terminal 121 is a terminal for receiving the battery voltage Vbat of the DC power source 40. The input terminal 122 is an example of the first terminal, and is a terminal for receiving the variable voltage Vcon of the converter circuit 10. The input terminal 121 is connected, outside the supply modulator 20, to the output terminal of the DC power source 40, and is connected, inside the supply modulator 20, to the switch S51. The input terminal 122 is connected, outside the supply modulator 20, to the output terminal 112 of the converter circuit 10, and is connected, inside the supply modulator 20, to the switch S52. It is noted that, in the present embodiment, the input terminal 121 is connected to the DC power source 40 without any other circuit component interposed therebetween, and the input terminal 122 is connected to the converter circuit 10 without any other circuit component interposed therebetween. In other words, the tracker circuit 1 can be miniaturized in that it does not have a switched-capacitor circuit that the tracker circuits in the related art operating in a digital ET mode have.

The output terminal 123 is a terminal for selectively supplying at least one of a plurality of discrete voltages to the power amplifier 2. The output terminal 123 is connected, outside the supply modulator 20, to the power amplifier 2, and is connected, inside the supply modulator 20, to the switches S51 and S52.

The switch S51 is connected between the input terminal 121 and the output terminal 123. Specifically, the switch S51 includes a terminal connected to the input terminal 121 and a terminal connected to the output terminal 123. In this connection configuration, the switch S51 can switch the connection and disconnection between the input terminal 121 and the output terminal 123 by being switched ON and OFF by a control signal from the digital control circuit 30.

The switch S52 is connected between the input terminal 122 and the output terminal 123. Specifically, the switch S52 includes a terminal connected to the input terminal 122 and a terminal connected to the output terminal 123. In this connection configuration, the switch S52 can switch the connection and disconnection between the input terminal 122 and the output terminal 123 by being switched ON and OFF by a control signal from the digital control circuit 30.

In an exemplary aspect, the capacitor C21 can be configured to function as a bypass capacitor and suppress the fluctuation of the battery voltage Vbat in response to the load fluctuation of the power amplifier 2. The capacitor C21 is connected between the ground and a path connecting the input terminal 121 and the switch S51.

In the present embodiment, the switches S51 and S52 are controlled to be exclusively turned ON. In other words, only one of the switches S51 and S52 is turned ON, and the other of the switches S51 and S52 is turned OFF. With such a configuration, the supply modulator 20 can output one voltage selected from the battery voltage Vbat and the variable voltage Vcon to the power amplifier 2.

The configuration of the supply modulator 20 shown in FIG. 4A is an example, and is not limited to such an example. In particular, the switches S51 and S52 may have any configuration and may be controlled in any way as long as at least one of the two input terminals 121 and 122 can be selectively connected to the output terminal 123. For example, both the switches S51 and S52 may be turned ON.

It is noted that when two or more discrete voltages are supplied from the converter circuit 10, the supply modulator 20 may further include one or more switches in addition to the switches S51 and S52.

### [2.3 Circuit Configuration of Digital Control Circuit 30]

Next, the circuit configuration of the digital control circuit 30 will be described with reference to FIG. 4A. The digital control circuit 30 includes a first controller 31, a second controller 32, and control terminals 131 to 134.

The first controller 31 can be configured to process a source-synchronous digital control signal (serial data signal) received from the RFIC 3 via the control terminals 131 and 132 to generate a control signal for controlling the converter circuit 10. ON/OFF of the switches S71 and S72 included in the converter circuit 10 are controlled by the control signal from the first controller 31. In other words, the converter circuit 10 converts the battery voltage Vbat into the variable voltage Vcon according to the serial data signal.

It is noted that the digital control signal processed by the first controller 31 is not limited to the source-synchronous digital control signal. For example, the first controller 31 may be configured to process a clock-embedded digital control signal. Further, the first controller 31 may be configured to generate a control signal for controlling the supply modulator 20.

In the present embodiment, one set of clock signal and data signal is used, but the digital control signal is not limited to one set of clock signal and data signal. For example, a plurality of sets of clock signal and data signal may be used as the digital control signal.

The second controller 32 be configured to can process digitally controlled level (DCL: Digital Control Logic/Line) signals (DCL1 and DCL2: parallel data signals) received from the RFIC 3 via the control terminals 133 and 134 to generate a control signal for controlling the supply modulator 20. The DCL signals (DCL1 and DCL2) are generated by the RFIC 3 based on an envelope signal of the radio frequency signal. The ON/OFF of the switches S51 and S52 included in the supply modulator 20 is controlled by the control signal from the second controller 32. In other words, the supply modulator 20 selects at least one of a plurality of discrete voltages according to the parallel data signal.

According to an exemplary aspect, each of the DCL signals (DCL1 and DCL2) is a 1-bit signal. Moreover, each of the plurality of discrete voltages including the battery voltage Vbat and the variable voltage Vcon is represented by a combination of two 1-bit signals. For example, the three discrete voltages are represented by “00”, “01”, and “10”. A gray code may be used to represent the voltage level.

In the present embodiment, two digitally controlled level (DCL) signals are used to control the supply modulator 20, but the number of DCL signals is not limited to two. For example, any number, such as 1 or 3 or more, of DCL signals may be used depending on the number of voltage levels, which are each selectable, of the supply modulator 20. Further, the digital control signals used to control the supply modulator 20 are not limited to the DCL signals.

Tracker circuits in the related art that supply a power supply voltage V_{ET} in a digital ET mode have a buck-boost converter circuit, a switched-capacitor circuit, and a supply modulator. Since the switched-capacitor circuit has a plurality of flying capacitors and a plurality of switches for performing charge and discharge complementarily in a plurality of phases, it has larger circuit scale and higher power consumption as compared to those of the converter circuits such as a buck-boost converter and a buck converter.

In contrast, as a configuration that supplies the power supply voltage V_{ET} to the power amplifier 2 in a digital ET mode, the tracker circuit 1 according to the present embodiment has the converter circuit 10 and the supply modulator 20, but does not have a switched-capacitor circuit. Therefore, with the tracker circuit 1 according to the present embodiment, miniaturization and low power consumption is realized.

### 3 Voltage Supply Method of Tracker Circuit 1

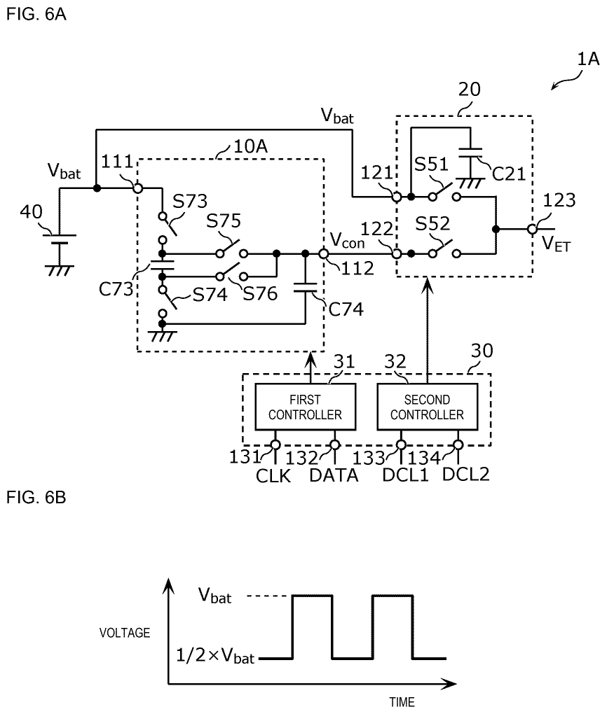

Next, a voltage supply method, which is a method of supplying a plurality of discrete voltages by the tracker circuit 1 configured as described above, will be described with reference to FIG. 5. FIG. 5 is a flowchart showing a voltage supply method according to the present embodiment.

First, the converter circuit 10 converts the battery voltage Vbat into the variable voltage Vcon (S20).

Next, the supply modulator 20 selectively outputs, based on the envelope signal, at least one of a plurality of discrete voltages including the battery voltage Vbat and the variable voltage Vcon to the power amplifier 2 (S30).

Thus, the tracker circuit 1 according to the present embodiment can supply the power supply voltage V_{ET} in a digital ET mode to the power amplifier 2 by the converter circuit 10 and the supply modulator 20 without using a switched-capacitor circuit. Therefore, miniaturization and low power consumption of the tracker circuit 1 is realized.

### 4 Circuit Configuration of Tracker Circuit 1A According to Modification 1

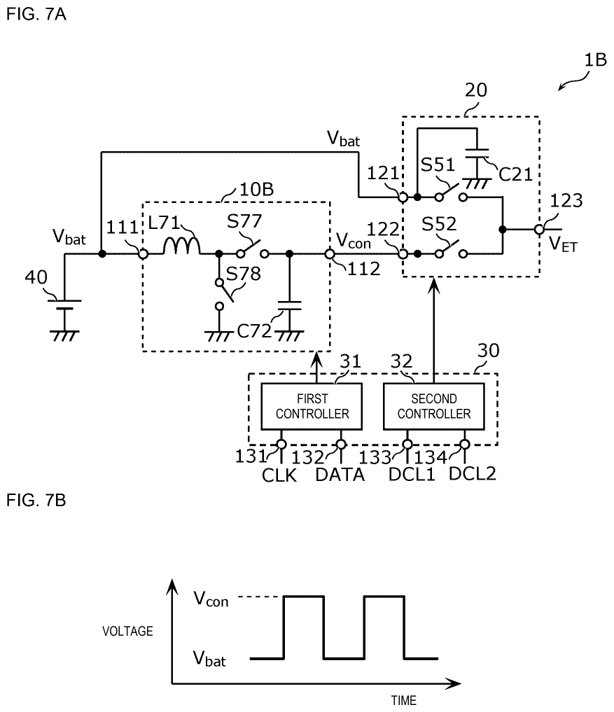

Next, the circuit configuration of a tracker circuit 1A according to Modification 1 will be described with reference to FIGS. 6A and 6B. FIG. 6A is a circuit configuration diagram of the tracker circuit 1A according to Modification 1 of the embodiment. FIG. 6B is a diagram showing the output waveform of a power supply voltage V_{ET} of the tracker circuit 1A according to Modification 1 of the embodiment. As shown in FIG. 6A, the tracker circuit 1A includes a converter circuit 10A, a supply modulator 20, a digital control circuit 30, and a DC power source 40. The tracker circuit 1A according to the present modification differs from the tracker circuit 1 according to the embodiment in the circuit configuration of the converter circuit 10A. Hereinafter, the tracker circuit 1A according to the present modification will be described focusing on the configurations different from those of the tracker circuit 1 according to the embodiment and omitting descriptions of the same configurations as those of the tracker circuit 1.

### [4.1 Circuit Configuration of Converter Circuit 10A]

The converter circuit 10A according to the present modification is a charge-pump type step-down circuit, and includes an input terminal 111, an output terminal 112, switches S73, S74, S75, and S76, and capacitors C73 and C74.

The input terminal 111 is a terminal for receiving the battery voltage Vbat from the DC power source 40. The input terminal 111 is connected, outside the converter circuit 10A, to the DC power source 40, and is connected, inside the converter circuit 10A, to one end of the switch S73.

The output terminal 112 is a terminal for supplying the variable voltage Vcon to the supply modulator 20. The output terminal 112 is connected, outside the converter circuit 10A, to the input terminal 122 of the supply modulator 20, and is connected, inside the converter circuit 10A, to one electrode of the capacitor C74.

One electrode of the capacitor C73 is connected to the other end of the switch S73 and one end of the switch S75, and the other electrode of the capacitor C73 is connected to one end of the switch S74 and one end of the switch S76.

One electrode of the capacitor C74 is connected to the other end of the switch S75 and the other end of the switch S76, and the other electrode of the capacitor C74 is connected to the other end of the switch S74 and the ground.

In the above connection configuration, the converter circuit 10A first (1) turns on the switches S73 and S76, and turns off the switches S74 and S75. Thus, the capacitors C73 and C74 are serially connected in a state where the battery voltage Vbat is applied, and when the capacitances of the capacitors C73 and C74 are equal, a voltage of ½×Vbat is generated in each of the capacitors C73 and C74. Next, the converter circuit 10A (2) turns off the switches S73 and S76, and turns on the switches S74 and S75. Thus, the capacitors C73 and C74 are connected in parallel in a state where the battery voltage Vbat is not applied, and a voltage of ½×Vbat is generated at the output terminal 112. In other words, the converter circuit 10A can lower the battery voltage Vbat to a first regulated voltage (=½×Vbat) lower than the battery voltage Vbat.

With the tracker circuit 1A according to the present modification, the power supply voltage V_{ET} outputted from the output terminal 123 has an output waveform as shown in FIG. 6B, for example. As the digital ET mode of the tracker circuit 1A, for example, the battery voltage Vbat is applied to a voltage corresponding to the peak power of the power amplifier 2, and the variable voltage Vcon is applied to a voltage corresponding to a power lower than the peak power. It is noted that the voltage corresponding to the peak power of the power amplifier 2 refers to a power supply voltage optimized for the power-added efficiency of the power amplifier 2 at the peak output power of the radio frequency signal amplified by the power amplifier 2.

Thus, the power supply voltage V_{ET} for the power level lower than the peak power of the power amplifier 2 can be supplied at the first regulated voltage (=½×Vbat). Further, since the charge-pump type converter circuit 10A does not include a power inductor, it can be further miniaturized compared to a converter circuit including a power inductor.

It is noted that the configuration of the charge-pump type converter circuit 10A shown in FIG. 6A is an example, and is not limited to such an example. For example, the number of capacitors may be 3 or more; and in such a case, it is possible to generate a first regulated voltage of 1/n×Vbat (n=an integer of 3 or more).

### 5 Circuit Configuration of Tracker Circuit 1B According to Modification 2

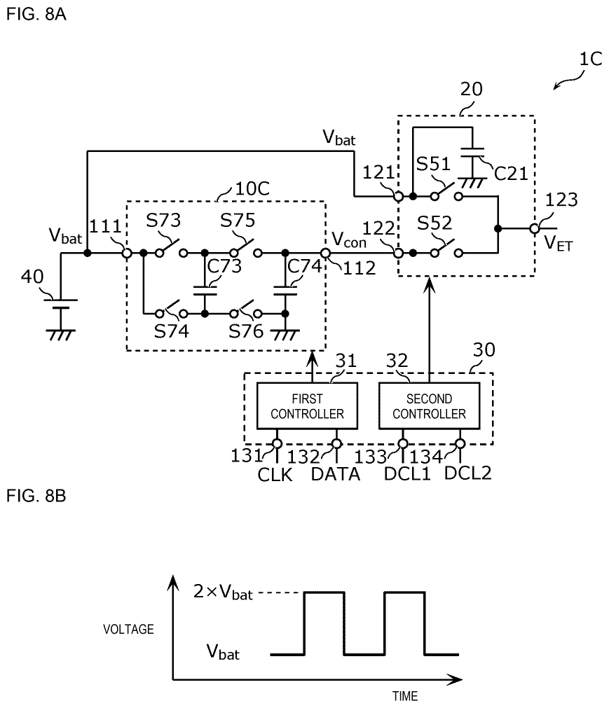

Next, the circuit configuration of a tracker circuit 1B according to Modification 2 will be described with reference to FIGS. 7A and 7B. FIG. 7A is a circuit configuration diagram of the tracker circuit 1B according to Modification 2 of the embodiment. FIG. 7B is a diagram showing the output waveform of a power supply voltage V_{ET} of the tracker circuit 1B according to Modification 2 of the embodiment. As shown in FIG. 7A, the tracker circuit 1B includes a converter circuit 10B, a supply modulator 20, a digital control circuit 30, and a DC power source 40. The tracker circuit 1B according to the present modification differs from the tracker circuit 1 according to the embodiment in the circuit configuration of the converter circuit 10B. Hereinafter, the tracker circuit 1B according to the present modification will be described focusing on the configurations different from those of the tracker circuit 1 according to the embodiment and omitting descriptions of the same configurations as those of the tracker circuit 1.

### [5.1 Circuit Configuration of Converter Circuit 10B]

The converter circuit 10B according to the present modification is a boost converter (step-up) circuit, and includes an input terminal 111, an output terminal 112, switches S77 and S78, a power inductor L71, and a capacitor C72.

The input terminal 111 is an example of the first input terminal, and is a terminal for receiving the battery voltage Vbat from the DC power source 40. The input terminal 111 is connected, outside the converter circuit 10B, to the DC power source 40, and is connected, inside the converter circuit 10B, to the input end of the power inductor L71.

The output terminal 112 is an example of the first output terminal, and is a terminal for supplying the variable voltage Vcon to the supply modulator 20. The output terminal 112 is connected, outside the converter circuit 10B, to the input terminal 122 (first terminal) of the supply modulator 20, and is connected, inside the converter circuit 10B, to the switch S77.

The power inductor L71 is an example of the first power inductor, and is an inductor used for raising and lowering a DC voltage. The input end of the power inductor L71 is connected to the input terminal 111, and the output end of the power inductor L71 is connected to the switches S77 and S78.

The switch S77 is an example of the first switch, and is connected between the output end of the power inductor L71 and the output terminal 112. Specifically, the switch S77 includes a terminal connected to the output end of the power inductor L71 and a terminal connected to the output terminal 112. In such a connection configuration, the switch S77 can switch the connection and disconnection between the output end of the power inductor L71 and the output terminal 112 by being switched ON and OFF.

The switch S78 is an example of the second switch, and is connected between the output end of the power inductor L71 and the ground. Specifically, the switch S78 includes a terminal connected to the output end of the power inductor L71 and a terminal connected to the ground. In such a connection configuration, the switch S78 can switch the connection and disconnection between the output end of the power inductor L71 and the ground by being switched ON and OFF.

The capacitor C72 is an example of the first capacitor, and is connected between the ground and the path between the switch S77 and the output terminal 112. Specifically, one of the two electrodes of the capacitor C72 is connected to the switch S77 and the output terminal 112, and the other of the two electrodes of the capacitor C72 is connected to the ground.

The converter circuit 10B configured as described above can convert the battery voltage Vbat (input voltage) into a variable voltage Vcon (first regulated voltage) higher than the battery voltage Vbat.

With the tracker circuit 1B according to the present modification, the power supply voltage V_{ET} output from the output terminal 123 has, for example, an output waveform as shown in FIG. 7B. As the digital ET mode of the tracker circuit 1B, for example, the variable voltage Vcon is applied to a voltage corresponding to the peak power of the power amplifier 2, and the battery voltage Vbat is applied to a voltage corresponding to a power lower than the peak power. It is noted that the voltage corresponding to the peak power of the power amplifier 2 refers to a power supply voltage optimized for the power-added efficiency of the power amplifier 2 at the peak output power of the radio frequency signal amplified by the power amplifier 2.

Thus, the power supply voltage V_{ET} Corresponding to the peak power of the power amplifier 2 can be supplied at the variable voltage Vcon (first regulated voltage).

It is noted that the configuration of the converter circuit 10B shown in FIG. 7A is an example, and is not limited to such an example. For example, some of the switches S77 and S78 may be replaced with diode(s) in an alterative aspect. Further, the configuration of the converter circuit 10B is an example, and is not limited to such an example. For example, the converter circuit 10B may be a charge pump circuit that can raise the voltage, that is composed of a capacitor and a switch, and that does not include the power inductor L71.

### 6 Circuit Configuration of Tracker Circuit 1C According to Modification 3

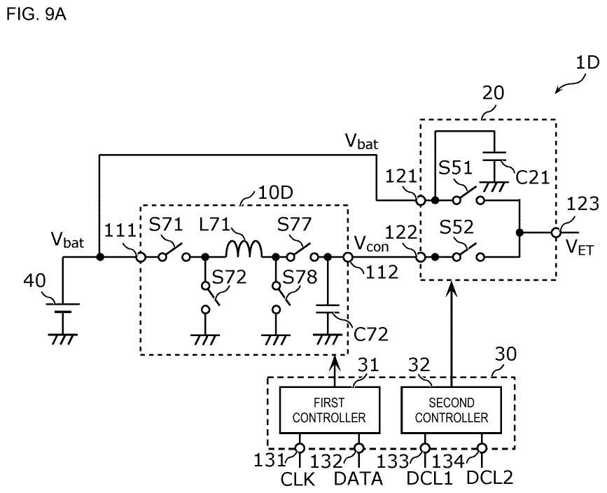

Next, the circuit configuration of a tracker circuit 1C according to Modification 3 will be described with reference to FIGS. 8A and 8B. FIG. 8A is a circuit configuration diagram of the tracker circuit 1C according to Modification 3 of the embodiment. FIG. 8B is a diagram showing the output waveform of a power supply voltage V_{ET} of the tracker circuit 1C according to Modification 3 of the embodiment. As shown in FIG. 8A, the tracker circuit 1C includes a converter circuit 10C, a supply modulator 20, a digital control circuit 30, and a DC power source 40. The tracker circuit 1C according to the present modification differs from the tracker circuit 1 according to the embodiment in the circuit configuration of the converter circuit 10C. Hereinafter, the tracker circuit 1C according to the present modification will be described focusing on the configurations different from those of the tracker circuit 1 according to the embodiment and omitting descriptions of the same configurations as those of the tracker circuit 1.

### [6.1 Circuit Configuration of Converter Circuit 10C]

The converter circuit 10C according to the present modification is a charge-pump type step-up circuit, and includes an input terminal 111, an output terminal 112, switches S73, S74, S75, and S76, and capacitors C73 and C74.

The input terminal 111 is a terminal for receiving the battery voltage Vbat from the DC power source 40. The input terminal 111 is connected, outside the converter circuit 10C, to the DC power source 40, and is connected, inside the converter circuit 10C, to one end of the switch S73 and one end of the switch S74.

The output terminal 112 is a terminal for supplying the variable voltage Vcon to the supply modulator 20. The output terminal 112 is connected, outside the converter circuit 10C, to the input terminal 122 of the supply modulator 20, and is connected, inside the converter circuit 10C, to one electrode of the capacitor C74.

One electrode of the capacitor C73 is connected to the other end of the switch S73 and one end of the switch S75, and the other electrode of the capacitor C73 is connected to the other end of the switch S74 and one end of the switch S76.

One electrode of the capacitor C74 is connected to the other end of the switch S75, and the other electrode of the capacitor C74 is connected to the other end of the switch S76 and the ground.

In the above connection configuration, the converter circuit 10C first (1) turns on the switches S73 and S76, and turns off the switches S74 and S75. Thus, the capacitor C73 is charged to be equal to the battery voltage Vbat. Next, the converter circuit 10C (2) turns off the switches S73 and S76, and turns on the switches S74 and S75. Thus, the capacitor C74 is charged to be equal to twice the battery voltage Vbat, and a voltage of 2×Vbat is generated at the output terminal 112. In other words, the converter circuit 10C can raise the battery voltage Vbat to a first regulated voltage (=2×Vbat) higher than the battery voltage Vbat.

With the tracker circuit 1C according to the present modification, the power supply voltage V_{ET} output from the output terminal 123 has an output waveform as shown in FIG. 8B, for example. As the digital ET mode of the tracker circuit 1C, for example, the first regulated voltage (=2×Vbat) is applied to a voltage corresponding to the peak power of the power amplifier 2, and the battery voltage Vbat is applied to a voltage corresponding to a power lower than the peak power. It is noted that the voltage corresponding to the peak power of the power amplifier 2 refers to a power supply voltage optimized for the power-added efficiency of the power amplifier 2 at the peak output power of the radio frequency signal amplified by the power amplifier 2.

Thus, the power supply voltage V_{ET} corresponding to the peak power of the power amplifier 2 can be supplied at the first regulated voltage (=2×Vbat). Further, since the charge-pump type converter circuit 10C does not include a power inductor, it can be further miniaturized compared to a converter circuit including a power inductor.

It is noted that the configuration of the charge-pump type converter circuit 10C shown in FIG. 8A is an example, and is not limited to such an example. For example, the number of capacitors may be 3 or more; and in such a case, it is possible to generate a first regulated voltage of n×Vbat (n=an integer of 3 or more).

### 7 Circuit Configuration of Tracker Circuit 1D According to Modification 4

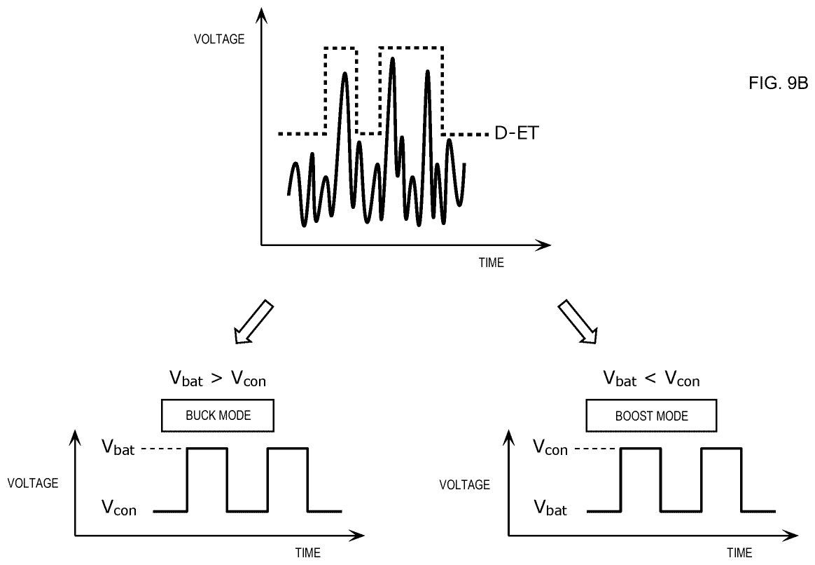

Next, the circuit configuration of a tracker circuit 1D according to Modification 4 will be described with reference to FIGS. 9A and 9B. FIG. 9A is a circuit configuration diagram of the tracker circuit 1D according to Modification 4 of the embodiment. FIG. 9B is a diagram showing the output waveform of a power supply voltage V_{ET} of the tracker circuit 1D according to Modification 4 of the embodiment. As shown in FIG. 9A, the tracker circuit 1D includes a converter circuit 10D, a supply modulator 20, a digital control circuit 30, and a DC power source 40. The tracker circuit 1D according to the present modification differs from the tracker circuit 1 according to the embodiment in the circuit configuration of the converter circuit 10D. Hereinafter, the tracker circuit 1D according to the present modification will be described focusing on the configurations different from those of the tracker circuit 1 according to the embodiment and omitting descriptions of the same configurations as those of the tracker circuit 1.

### [7.1 Circuit Configuration of Converter Circuit 10D]

The converter circuit 10D according to the present modification is a buck-boost converter (step-up/step-down) circuit, and includes an input terminal 111, an output terminal 112, switches S71, S72, S77, and S78, a power inductor L71, and a capacitor C72.

The input terminal 111 is an example of the first input terminal, and is a terminal for receiving the battery voltage Vbat from the DC power source 40. The input terminal 111 is connected, outside the converter circuit 10D, to the DC power source 40, and is connected, inside the converter circuit 10D, to the switch S71.

The output terminal 112 is an example of the first output terminal, and is a terminal for supplying the variable voltage Vcon to the supply modulator 20. The output terminal 112 is connected, outside the converter circuit 10D, to the input terminal 122 (first terminal) of the supply modulator 20, and is connected, inside the converter circuit 10D, to the switch S77.

The power inductor L71 is an example of the first power inductor, and is an inductor used for raising and lowering a DC voltage. The input end of the power inductor L71 is connected to the switches S71 and S72, and the output end of the power inductor L71 is connected to the switches S77 and S78.

The switch S71 is an example of the first switch, and is connected between the input terminal 111 and the input end of the power inductor L71. Specifically, the switch S71 includes a terminal connected to the input terminal 111 and a terminal connected to the input end of the power inductor L71. In such a connection configuration, the switch S71 can switch the connection and disconnection between the input terminal 111 and the input end of the power inductor L71 by being switched ON and OFF.

The switch S72 is an example of the second switch, and is connected between the input end of the power inductor L71 and the ground. Specifically, the switch S72 includes a terminal connected to the input end of the power inductor L71 and a terminal connected to the ground. In such a connection configuration, the switch S72 can switch the connection and disconnection between the input end of the power inductor L71 and the ground by being switched ON and OFF.

The switch S77 is an example of a third switch, and is connected between the output end of the power inductor L71 and the output terminal 112. Specifically, the switch S77 includes a terminal connected to the output end of the power inductor L71 and a terminal connected to the output terminal 112. In such a connection configuration, the switch S77 can switch the connection and disconnection between the output end of the power inductor L71 and the output terminal 112 by being switched ON and OFF.

The switch S78 is an example of a fourth switch, and is connected between the output end of the power inductor L71 and the ground. Specifically, the switch S78 includes a terminal connected to the output end of the power inductor L71 and a terminal connected to the ground. In this connection configuration, the switch S78 can switch the connection and disconnection between the output end of the power inductor L71 and the ground by being switched ON and OFF.

The capacitor C72 is an example of the first capacitor, and is connected between the ground and the path between the switch S77 and the output terminal 112. Specifically, one of the two electrodes of the capacitor C72 is connected to the switch S77 and the output terminal 112, and the other of the two electrodes of the capacitor C72 is connected to the ground.

The converter circuit 10D configured as described above can convert the battery voltage Vbat into a variable voltage Vcon.

It is noted that the configuration of the converter circuit 10D shown in FIG. 9A is an example, and is not limited to such an example. For example, some of the switches S71, S72, S77, and S78 may be replaced with diode(s) in an alterative aspect. Further, the configuration of the converter circuit 10D is an example, and is not limited to such an example. For example, the converter circuit 10D may be a charge pump circuit that can raise and lower the voltage, that is composed of a capacitor and a switch, and that does not include the power inductor L71.

In the tracker circuit 1D having the circuit configuration described above, the power supply voltage V_{ET} output from the output terminal 123 has, for example, two types of output waveforms as shown in the lower part of FIG. 9B.

When the battery voltage Vbat is equal to or higher than a voltage corresponding to the peak power of the radio frequency signal amplified by the power amplifier 2, the converter circuit 10D converts the battery voltage Vbat into a variable voltage Vcon which is lower than the battery voltage Vbat in the buck mode. As a digital ET mode in a buck mode, for example, the battery voltage Vbat is applied to a voltage corresponding to the peak power of the power amplifier 2, and the variable voltage Vcon is applied to a voltage corresponding to a power lower than the peak power.

When the battery voltage Vbat is lower than the voltage corresponding to the peak power of the radio frequency signal amplified by the power amplifier 2, the converter circuit 10D converts the battery voltage Vbat into a variable voltage Vcon which is higher than the battery voltage Vbat in the boost mode. As a digital ET mode in a boost mode, for example, the variable voltage Vcon is applied to a voltage corresponding to the peak power of the power amplifier 2, and the battery voltage Vbat is applied to a voltage corresponding to a power lower than the peak power.

It is noted that the voltage corresponding to the peak power of the power amplifier 2 refers to a power supply voltage optimized for the power-added efficiency of the power amplifier 2 at the peak output power of the radio frequency signal amplified by the power amplifier 2.

Thus, by comparing the battery voltage Vbat with the voltage corresponding to the peak power of the power amplifier 2, it is possible to appropriately make the battery voltage Vbat and the variable voltage Vcon correspond to either the power supply voltage corresponding to the peak power or a power supply voltage lower than the power supply voltage corresponding to the peak power. Thus, a high-efficiency tracker circuit 1D can be provided even when the battery voltage Vbat fluctuates due to, for example, the aging state, the deterioration state, and/or the like of the DC power source 40. Therefore, with the tracker circuit 1D according to the present modification, high efficiency, miniaturization, and low power consumption is realized.

It is noted that the configuration of the converter circuit 10D shown in FIG. 9A is an example, and is not limited to such an example. For example, some of the switches S71, S72, S77, and S78 may be replaced with diode(s) in an alterative aspect. Further, the configuration of the converter circuit 10D is an example, and is not limited to such an example. For example, the converter circuit 10D may be a charge pump circuit that can raise and lower the voltage, that is composed of a capacitor and a switch, and that does not include the power inductor L71.

### 8 Voltage Supply Method of Tracker Circuit 1D

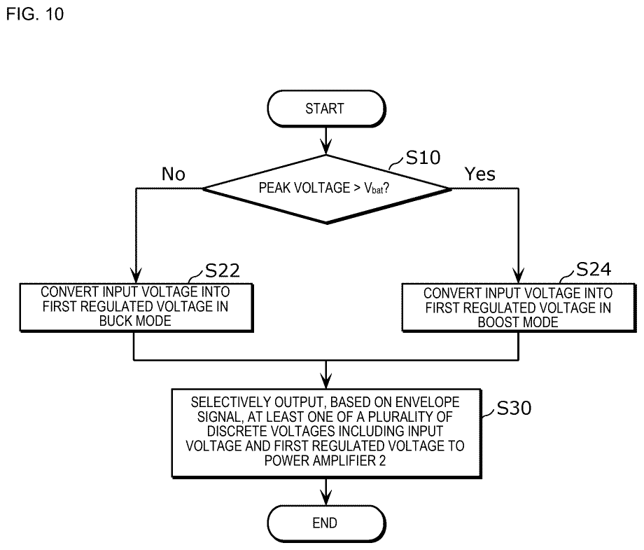

Next, a voltage supply method, which is a method of supplying a plurality of discrete voltages by the tracker circuit 1D configured as described above, will be described with reference to FIG. 10. FIG. 10 is a flowchart showing a voltage supply method according to Modification 4 of the embodiment.

When the battery voltage Vbat is equal to or higher than the voltage corresponding to the peak power of the radio frequency signal amplified by the power amplifier 2 (“No” in S10: peak voltage≤Vbat), the converter circuit 10D converts the battery voltage Vbat into a variable voltage Vcon lower than the battery voltage Vbat in the buck mode (S22). In other words, a plurality of discrete voltages are generated from the battery voltage Vbat and the variable voltage Vcon lower than the battery voltage Vbat.

When the battery voltage Vbat is lower than the voltage corresponding to the peak power of the radio frequency signal amplified by the power amplifier 2 (“Yes” in S10: peak voltage>Vbat), the converter circuit 10D converts the battery voltage Vbat into a variable voltage Vcon higher than the battery voltage Vbat in the boost mode (S24). In other words, a plurality of discrete voltages are generated from the battery voltage Vbat and the variable voltage Vcon higher than the battery voltage Vbat.

Next, the supply modulator 20 selectively outputs, based on the envelope signal, at least one of a plurality of discrete voltages including the battery voltage Vbat and the variable voltage Vcon to the power amplifier 2 (S30).

Thus, the tracker circuit 1D according to the present embodiment can supply the power supply voltage V_{ET} in a digital ET mode to the power amplifier 2 by the converter circuit 10D and the supply modulator 20 without using a switched-capacitor circuit. Further, by comparing the battery voltage Vbat with the voltage corresponding to the peak power of the power amplifier 2, it is possible to appropriately make the battery voltage Vbat and the variable voltage Vcon correspond to either the power supply voltage corresponding to the peak power or a power supply voltage lower than the power supply voltage corresponding to the peak power. Thus, a high-efficiency tracker circuit 1D can be provided even when the battery voltage Vbat fluctuates due to, for example, the aging state, the deterioration state, and/or the like of the DC power source 40. Therefore, high efficiency, miniaturization, and low power consumption of the tracker circuit 1D can be provided.

### 9 Mounting Configuration of Tracker Module 1E

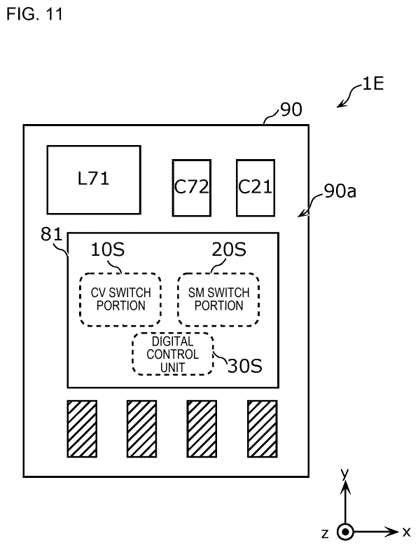

FIG. 11 is a plan view of a tracker module 1E according to the embodiment. The tracker module 1E is obtained by modularizing the tracker circuit 1 according to the embodiment, and includes a converter circuit 10, a supply modulator 20, and a digital control circuit 30.

As shown in FIG. 11, the tracker module 1E includes a module laminate 90 and an integrated circuit 81. It is noted that, in FIG. 11, wiring for connecting a plurality of circuit components disposed on the module laminate 90 is omitted. Further, in FIG. 11, a resin member and a shield electrode layer disposed on a main surface 90a of the module laminate 90 are not shown. It is also noted that the resin member and the shield electrode layer may be omitted in exemplary aspects. In FIG. 11, hatched blocks represent optional circuit components which mat be omitted in exemplary aspects of the present disclosure.

The module laminate 90 has the main surface 90a. A ground plane and the like is formed in the module laminate 90 and on the main surface 90a. In FIG. 11, the module laminate 90 has a rectangular shape in plan view; however, the shape of the module laminate 90 is not limited to rectangular shape.

Examples of those can be used as the module laminate 90 include, but are not limited to, a substrate having a multilayer structure formed by stacking a plurality of dielectric layers, and a printed circuit board; in which examples of the substrate having a multilayer structure formed by stacking a plurality of dielectric layers include a Low Temperature Co-fired Ceramics (LTCC) substrate or a High Temperature Co-fired Ceramics (HTCC) substrate, a component-embedded board, and a substrate having a redistribution layer (RDL).

According to an exemplary aspect, the integrated circuit 81 is one of the integrated circuits forming the tracker circuit 1. The integrated circuit 81 is disposed on the main surface 90a of the module laminate 90, and has a CV switch portion 10S, an SM switch portion 20S, and a digital control unit 30S. The CV switch portion 10S includes the switches S71 and S72 of the converter circuit 10. The SM switch portion 20S includes the switches S51 and S52 of the supply modulator 20. The digital control unit 30S includes the digital control circuit 30.

The integrated circuit 81 may include at least one switch included in the converter circuit 10 and at least one switch included in the supply modulator 20, and does not necessarily include the digital control unit 30S in an exemplary aspect.

In FIG. 11, the integrated circuit 81 has a rectangular shape in plan view of the module laminate 90, but the shape of the integrated circuit 81 is not limited to a rectangular shape.

The integrated circuit 81 may be formed by using, for example, Complementary Metal Oxide Semiconductor (CMOS), and may specifically be manufactured by a Silicon on Insulator (SOI) process. It is noted that the integrated circuit 81 is not limited to CMOS as would be appreciated to one skilled in the art.

Since the tracker module 1E according to the present embodiment does not include a switched-capacitor circuit, miniaturization and low power consumption is realized.

The tracker module 1E further includes a power inductor L71 and a capacitor C72 included in the converter circuit 10, and a capacitor C21 included in the supply modulator 20. The power inductor L71 and the capacitors C72 and C21 are disposed on the main surface 90a.

Since the tracker module 1E according to the present embodiment does not include a switched-capacitor circuit, the number of components of the tracker module 1E can be reduced and the area can be saved. From this viewpoint, since the component mounting density of the tracker module 1E can be reduced, the tracker module 1E can be miniaturized without deteriorating heat dissipation even when the power inductor L71 having high heat generation and large size is disposed on the module laminate 90.

It is noted that the power inductor L71 may be disposed outside the tracker module 1E in an exemplary aspect.

According to an exemplary aspect, each of the capacitors C72 and C21 is mounted as a chip capacitor. The chip capacitor can be a surface mount device (SMD) forming a capacitor. Moreover, it is noted that each of the capacitors C72 and C21 is not limited to a chip capacitor, but may be included in an integrated passive device (IPD) or included in the integrated circuit 81, for example.

At least one of the integrated circuit 81, the capacitors C72 and C21, and the power inductor L71 may be disposed inside the module laminate 90 or on a main surface facing the main surface 90a.

### 10 Technical Effects

As described above, the tracker circuit 1 according to the present embodiment includes a converter circuit 10 configured to convert a battery voltage Vbat into a first regulated voltage, and a supply modulator 20 that receives the battery voltage Vbat and the first regulated voltage. The supply modulator 20 outputs a modulated voltage to a power amplifier 2 by selectively outputting at least one of a plurality of discrete voltages including the battery voltage Vbat and the first regulated voltage.

With such a configuration, the tracker circuit 1, as a configuration that supplies the power supply voltage V_{ET} to the power amplifier 2 in a digital ET mode, has the converter circuit 10 and the supply modulator 20, but does not have a switched-capacitor circuit. Therefore, with the tracker circuit 1 according to the present embodiment, miniaturization and low power consumption is realized.

Further, for example, in the tracker circuit 1D according to Modification 4, the converter circuit 10D is a buck-boost converter circuit.

With such a configuration, the converter circuit 10D can output both a first regulated voltage higher than the battery voltage Vbat and a first regulated voltage lower than the battery voltage Vbat.

Further, for example, in the tracker circuit 1D, when the battery voltage Vbat is equal to or higher than a voltage corresponding to a peak power of a radio frequency signal amplified by the power amplifier 2, the converter circuit 10D converts the battery voltage Vbat into the first regulated voltage in a buck mode, and when the battery voltage Vbat is lower than the voltage corresponding to the peak power of the radio frequency signal amplified by the power amplifier 2, the converter circuit 10D converts the battery voltage Vbat into the first regulated voltage in a boost mode.

With such a configuration, by comparing the battery voltage Vbat with the voltage corresponding to the peak power of the power amplifier 2, it is possible to appropriately make the battery voltage Vbat and the first regulated voltage correspond to either a power supply voltage corresponding to the peak power or a power supply voltage lower than the power supply voltage corresponding to the peak power. Thus, a high-efficiency tracker circuit 1D can be provided even when the battery voltage Vbat fluctuates due to, for example, the aging state, the deterioration state, and/or the like of the DC power source 40.

Further, for example, in the tracker circuit 1D, the converter circuit 10D includes a power inductor L71, an input terminal 111 that receives the battery voltage Vbat, an output terminal 112 that is connected to an input terminal 122 of the supply modulator 20, a switch S71 connected between an input end of the power inductor L71 and the input terminal 111, a switch S72 connected between the input end of the power inductor L71 and a ground, a switch S77 connected between an output end of the power inductor L71 and the output terminal 112, a switch S78 connected between the output end of the power inductor L71 and the ground, and a capacitor C72 connected between the ground and a path between the switch S77 and the output terminal 112.

With such a configuration, the variable voltage Vcon, which is one of a plurality of discrete voltages, can be generated by a step-up/step-down circuit composed of one power inductor, four switches, and one capacitor, so that the configuration of the tracker circuit 1D is simplified.

Further, for example, in the tracker circuit 1 according to the embodiment, the converter circuit 10 is a buck converter circuit, and the first regulated voltage is lower than the battery voltage Vbat.

With such a configuration, the converter circuit 10 can output a first regulated voltage lower than the battery voltage Vbat.

Further, for example, in the tracker circuit 1 according to the embodiment, the converter circuit 10 includes a power inductor L71, an input terminal 111 that receives the battery voltage Vbat, an output terminal 112 that is connected to an input terminal 122 of the supply modulator 20, a switch S71 connected between an input end of the power inductor L71 and the input terminal 111, a switch S72 connected between the input end of the power inductor L71 and the ground, and a capacitor C72 connected between the ground and a path between the power inductor L71 and the output terminal 112.

With such a configuration, the first regulated voltage, which is one of a plurality of discrete voltages, can be generated by a step-down circuit composed of one power inductor, two switches, and one capacitor, so that the configuration of the tracker circuit 1 is simplified.

Further, for example, in the tracker circuit 1B according to Modification 2, the converter circuit 10B is a boost converter circuit, and the first regulated voltage is higher than the battery voltage Vbat.

With such a configuration, the converter circuit 10B can output a first regulated voltage higher than the battery voltage Vbat.

Further, for example, in the tracker circuit 1B, the converter circuit 10B includes a power inductor L71, an input terminal 111 that receives the battery voltage Vbat and that is connected to an input end of the power inductor L71, an output terminal 112 that is connected to an input terminal 122 of the supply modulator 20, a switch S77 that is connected between an output end of the power inductor L71 and the output terminal 112, a switch S78 that is connected between the output end of the power inductor L71 and a ground, and a capacitor C72 connected between the ground and a path between the switch S77 and the output terminal 112.

With such a configuration, the first regulated voltage, which is one of a plurality of discrete voltages, can be generated by a step-up circuit composed of one power inductor, two switches, and one capacitor, so that the configuration of the tracker circuit 1B is simplified.

Further, for example, in the tracker circuit 1 (1A, 1B, 1C, 1D), the converter circuit 10 (10A, 10B, 10C, 10D) is configured to convert the battery voltage Vbat into the first regulated voltage in accordance with a serial data signal, and the supply modulator 20 is configured to select at least one of the plurality of discrete voltages in accordance with a parallel data signal.

With such a configuration, since the supply modulator 20 operates according to the parallel data signal, the supply modulator 20 can operate at a higher speed in a digital ET mode. Therefore, in a digital ET mode, the tracking property of the power supply voltage V_{ET} to the envelope is improved, and the power-added efficiency of the power amplifier 2 is improved.

Further, for example, in the tracker circuit 1 (1A, 1B, 1C, 1D), the converter circuit 10 (10A, 10B, 10C, 10D) and the supply modulator 20 are directly connected to each other.

With such a configuration, since the tracker circuit 1 (1A, 1B, 1C, 1D) does not have a switched-capacitor circuit, miniaturization and low power consumption of the tracker circuit 1 (1A, 1B, 1C, 1D) can be provided.

Further, for example, in the tracker circuit 1 (1A, 1B, 1C, 1D), the power amplifier 2 and the supply modulator 20 are directly connected to each other.

With such a configuration, since there is no filter circuit between the power amplifier 2 and the supply modulator 20, the tracker circuit 1 (1A, 1B, 1C, 1D) can be miniaturized.

Further, for example, the tracker module 1E according to the embodiment includes a module laminate 90 and an integrated circuit 81 disposed on the module laminate 90. The integrated circuit 81 includes a switch included in a converter circuit 10 configured to convert a battery voltage Vbat into a first regulated voltage and a switch included in a supply modulator 20 that receives the battery voltage Vbat and the first regulated voltage. The supply modulator 20 selectively outputs, based on an envelope signal, at least one of a plurality of discrete voltages including the battery voltage Vbat and the first regulated voltage to the power amplifier 2.

With such a configuration, since the tracker module 1E does not include a switched-capacitor circuit, miniaturization and low power consumption is realized.

Further, for example, in the tracker module 1E, the converter circuit 10 includes a power inductor L71, and the power inductor L71 is disposed on the module laminate 90.

Since the tracker module 1E does not include a switched-capacitor circuit, the number of components of the tracker module 1E can be reduced and the area can be saved. From this viewpoint, since the component mounting density of the tracker module 1E can be reduced, the tracker module 1E can be miniaturized without deteriorating heat dissipation even when the power inductor L71 having a large heat generation and a large size is disposed on the module laminate 90.

A voltage supply method according to the present embodiment includes converting a battery voltage Vbat into a first regulated voltage (S20), and selectively outputting, based on an envelope signal, at least one of a plurality of discrete voltages including the battery voltage Vbat and the first regulated voltage to the power amplifier 2 (S30).

Thus, the tracker circuit 1 according to the present embodiment can supply the power supply voltage V_{ET} in a digital ET mode to the power amplifier 2 by the converter circuit 10 and the supply modulator 20 without using the switched-capacitor circuit. Therefore, miniaturization and low power consumption of the tracker circuit 1 is realized.

Further, for example, in the voltage supply method of the tracker circuit 1D according to Modification 4, when the battery voltage Vbat is equal to or higher than a voltage corresponding to a peak power of a radio frequency signal amplified by the power amplifier 2, the plurality of discrete voltages are generated from the battery voltage Vbat and the first regulated voltage lower than the battery voltage Vbat, and when the battery voltage Vbat is lower than the voltage corresponding to the peak power of the radio frequency signal amplified by the power amplifier 2, the plurality of discrete voltages are generated from the battery voltage Vbat and the first regulated voltage higher than the battery voltage Vbat.

Thus, by comparing the battery voltage Vbat with the voltage corresponding to the peak power of the power amplifier 2, it is possible to appropriately make the battery voltage Vbat and the variable voltage Vcon correspond to either the power supply voltage corresponding to the peak power or a power supply voltage lower than the power supply voltage corresponding to the peak power. Thus, a high-efficiency tracker circuit 1D can be provided even when the battery voltage Vbat fluctuates due to, for example, the aging state, the deterioration state, and/or the like of the DC power source 40. Therefore, high efficiency, miniaturization, and low power consumption of the tracker circuit 1D can be provided.

### ADDITIONAL EXEMPLARY EMBODIMENTS

The tracker circuit, tracker module, and voltage supply method according to the exemplary aspects of the present disclosure have been described based on the embodiment described above; however, the tracker circuit, tracker module, and voltage supply method according to the present disclosure are not limited to the above embodiment. The exemplary aspects of the present disclosure also include other embodiments realized by combining any of the components in the embodiment described above, modifications obtained by applying various variations conceived by those skilled in the art to the embodiment described above without departing from the spirit of the exemplary aspects of the present disclosure, and various devices incorporating the tracker circuit and tracker module described above.

For example, other circuit elements, wiring and/or the like may be inserted between the paths connecting each circuit element and signal path disclosed in the drawings in the circuit configuration of various circuits according to each embodiment described above. For example, an inductor and/or a capacitor may be inserted between the tracker circuit 1 and the power amplifier 2.

The tracker circuit 1 according to the above embodiment may include a plurality of supply modulators. In such a case, the tracker circuit 1 can supply different voltages to a plurality of power amplifiers.

The exemplary aspects of the present disclosure provide for a tracker circuit that is configured to supply voltages to a power amplifier and can be widely used in communication devices such as mobile phones.

### REFERENCE SIGNS LIST

1, 1A, 1B, 1C, 1D tracker circuit
1E tracker module
2 power amplifier
3 RFIC
4 antenna
5 communication device
10, 10A, 10B, 10C, 10D converter circuit
10S CV switch portion
20 supply modulator
20S SM switch portion
30 digital control circuit
30S digital control unit
31 first controller
32 second controller
40 DC power source
81 integrated circuit
90 module laminate
90a main surface
111, 121, 122, 211 input terminal
112, 123, 212 output terminal
131, 132, 133, 134 control terminal
210 amplification transistor
221 collector terminal
222 emitter terminal

1. A tracker circuit comprising:
a first converter circuit configured to convert an input voltage into a first regulated voltage; and
a supply modulator configured to:
receive the input voltage and the first regulated voltage, and
output a modulated voltage to a power amplifier by selectively outputting at least one discrete voltage of a plurality of discrete voltages that includes the input voltage and the first regulated voltage.

2. The tracker circuit according to claim 1, wherein the first converter circuit is a buck-boost converter circuit.

3. The tracker circuit according to claim 2, wherein the first converter circuit is configured to convert the input voltage into the first regulated voltage in a buck mode when the input voltage is equal to or higher than a voltage that corresponds to a peak power of a radio frequency signal amplified by the power amplifier.

4. The tracker circuit according to claim 3, wherein the first converter circuit is configured to convert the input voltage into the first regulated voltage in a boost mode when the input voltage is lower than the voltage that corresponds to the peak power of the radio frequency signal amplified by the power amplifier.

5. The tracker circuit according to claim 2, wherein the first converter circuit includes:
a first power inductor;
a first input terminal configured to receive the input voltage;
a first output terminal that is connected to a first terminal of the supply modulator;
a first switch that is connected between an input end of the first power inductor and the first input terminal;
a second switch that is connected between the input end of the first power inductor and a ground;
a third switch that is connected between an output end of the first power inductor and the first output terminal;
a fourth switch that is connected between the output end of the first power inductor and the ground; and
a first capacitor that is connected between the ground and a path between the third switch and the first output terminal.

6. The tracker circuit according to claim 1, wherein the first converter circuit is a buck converter circuit, and the first regulated voltage is lower than the input voltage.

7. The tracker circuit according to claim 6, wherein the first converter circuit includes:
a first power inductor;
a first input terminal configured to receive the input voltage;
a first output terminal that is connected to a first terminal of the supply modulator;
a first switch that is connected between an input end of the first power inductor and the first input terminal;
a second switch that is connected between the input end of the first power inductor and a ground; and
a first capacitor that is connected between the ground and a path between the first power inductor and the first output terminal.

8. The tracker circuit according to claim 1, wherein the first converter circuit is a boost converter circuit, and the first regulated voltage is higher than the input voltage.

9. The tracker circuit according to claim 8, wherein the first converter circuit includes:
a first power inductor;
a first input terminal configured to receive the input voltage and that is connected to an input end of the first power inductor;
a first output terminal that is connected to a first terminal of the supply modulator;
a first switch that is connected between an output end of the first power inductor and the first output terminal;
a second switch that is connected between the output end of the first power inductor and a ground; and
a first capacitor that is connected between the ground and a path between the first switch and the first output terminal.

10. The tracker circuit according to claim 1, wherein:
the first converter circuit is configured to convert the input voltage into the first regulated voltage in accordance with a serial data signal, and
the supply modulator is configured to select the at least one discrete voltage in accordance with a parallel data signal.

11. The tracker circuit according to claim 1, wherein the first converter circuit is directly connected to the supply modulator.

12. The tracker circuit according to claim 1, wherein the power amplifier is directly connected the supply modulator.

13. A tracker module comprising:
a module laminate; and
an integrated circuit disposed on the module laminate, the integrated circuit including a switch included in a first converter circuit configured to convert an input voltage into a first regulated voltage, and a switch included in a supply modulator that is configured to receive the input voltage and the first regulated voltage,
wherein the supply modulator is further configured to selective output, based on an envelope signal, at least one discrete voltage of a plurality of discrete voltages that includes the input voltage and the first regulated voltage to a power amplifier.

14. The tracker module according to claim 13, wherein the first converter circuit includes a power inductor that is disposed on the module laminate.

15. The tracker module according to claim 13, wherein the first converter circuit is a buck-boost converter circuit.

16. The tracker module according to claim 15, wherein the first converter circuit includes:
a first power inductor;
a first input terminal configured to receive the input voltage;
a first output terminal that is connected to a first terminal of the supply modulator;
a first switch that is connected between an input end of the first power inductor and the first input terminal;
a second switch that is connected between the input end of the first power inductor and a ground;
a third switch that is connected between an output end of the first power inductor and the first output terminal;
a fourth switch that is connected between the output end of the first power inductor and the ground; and
a first capacitor that is connected between the ground and a path between the third switch and the first output terminal.

17. The tracker module according to claim 13, wherein the first converter circuit is a buck converter circuit, and the first regulated voltage is lower than the input voltage.

18. A voltage supply method comprising:
converting an input voltage into a first regulated voltage; and
selectively outputting, based on an envelope signal, at least one discrete voltage of a plurality of discrete voltages that includes the input voltage and the first regulated voltage to a power amplifier.

19. The voltage supply method according to claim 18, further comprising generating the plurality of discrete voltages from the input voltage and the first regulated voltage lower than the input voltage when the input voltage is equal to or higher than a voltage that corresponds to a peak power of a radio frequency signal amplified by the power amplifier.

20. The voltage supply method according to claim 19, further comprising generating the plurality of discrete voltages from the input voltage and the first regulated voltage higher than the input voltage when the input voltage is lower than the voltage that corresponds to the peak power of the radio frequency signal amplified by the power amplifier.
